(19) United States
(12) Patent Application Publication
(10) Pub. No.: US 2023/0187569 A9
(43) Pub. Date: Jun. 15, 2023

(54) SOLAR CELL COMPRISING PHOTOVOLTAIC LINED OPTICAL CAVITY WITH CUSTOMIZED OPTICAL FILL, METHODS FOR MANUFACTURING THE SAME AND SOLAR PANELS COMPRISING THE SAME

(71) Applicant: SOLAR EARTH TECHNOLOGIES LTD., Vancouver (CA)

(72) Inventors: Shima ALAGHA, Coquitlam (CA); Michael Brian WHITWICK, Surrey (CA); Oliver ZIMMERMANN, Bowen Island (CA); Christopher MCCAHON, Delta (CA); Meng WANG, Vancouver (CA)

(21) Appl. No.: 17/787,411

(22) PCT Filed: Dec. 18, 2020
(86) PCT No.: PCT/IB2020/062219

§ 371 Date: Jun. 20, 2022

Related U.S. Application Data
(60) Provisional application No. 62/951,215, filed on Dec. 20, 2019.

(51) Int. Cl. H01L 31/0445; H01L 31/054; H01L 31/055; H02S 40/22; H01L 31/0352

(52) U.S. Cl. CPC H01L 31/0445; H01L 31/0547; H01L 31/055; H02S 40/22; H01L 31/035281

(57) ABSTRACT

The present invention relates to photovoltaic lined optical cavity for a robust power generating apparatus consisting of said cavities and manufacturing methods for said cavities. The photovoltaic lined optical cavity comprises of an optical core, a base substrate, photovoltaic layers lining the optical core, and optical elements. The photovoltaic lined optical cavity is optimized for the light capture of solar radiation and sufficient integrity against mechanical loads.

### FIELD OF THE INVENTION

The present invention relates to the field of solar energy production and more specifically to a solar cell design incorporating light management features that increase efficiency of solar power generation systems.

### BACKGROUND OF THE INVENTION

Solar power is accelerating as a mainstream power generation source in global markets. To further broaden its economic value, greater productivity of solar power system is desired by customers and greater flexibility in the environments in which such systems may be used.

In solar energy capture, light is adsorbed in a semiconducting material, imitating the creation electron hole pairs by exciting an electron across the semiconductor's bandgap. An internal electric field (typically created by a doped homojunction or heterojunction interface) separates the carriers and drives them to the collection electrodes. The collection of the sun's energy in a solar cell depends on several factorssuch as its reflectance, thermodynamic efficiency, charge carrier separation efficiency, charge carrier collection efficiency and conduction efficiency values. A solar cell will consist of two collecting electrodes (consisting of metallic or transparent conducting oxide (TCO) layers), a semiconductor with a doped homojunction or heterojunction interface to generate an internal field, and often surface structures and anti-reflective coatings to help with light capture. Solar cell efficiency is usually characterized by quantities easily measured in a laboratory setting, such as quantum efficiency, open-circuit voltage (VOC) ratio, and fill factor. The efficiency of the solar cells relates to the annual energy output of the photovoltaic system, in combination with latitude and climate.

A solar cell generates the most power when its surface is perpendicular to the sun's incoming rays. The incident solar angle changes continuously over the course of the day and throughout the year. In utility-scale power generation, solar modules are either used in conjunction with a sun tracking system, which rotates the module, or mounted at a fixed tilt; at the same angle as the latitude of the module's location. There is a trend towards combining solar modules with existing structures, such as rooftops, vehicles, windows or roads. In building these integrated photovoltaics, sun tracking or tilt mounting are not feasible options as the orientation of the solar module is largely determined by the mounting structure.

Efficiencies of a solar cell depend on the design optimization of these components, balancing light capture with optical losses and carrier recombination. Roughly, the semiconductor's thickness (maximized) and surface structures are used to increase light capture, TCO and shading metallic contacts create losses, and the semiconductor's thickness/material qualities (minimize/maximize) and integral electric field are used to decrease recombination. There are numerous materials and strategies to yield viable solar cells ranging from simple solutions that could be made in a simple kitchen with a solid working knowledge of chemistry; l to world-record, crystalline multi junction multi-semiconductors manufactured in advanced nanofabrication facilities. For cost-effective commercial applications, PN junction silicon solar cells currently dominate the market, with CIGS, CdTe, heterojunction silicon and silicon thin film solutions filling niche applications. Typical, commercially-iable state-of-art solar cell conversion rates are about 10-24% and solar modules converting 8-15% of the suns energy nto electric power.

A variety of means to improve the overall efficiency of solar cells and provide photovoltaic devices with improved conversion rates have been explored over recent years. These include: 1) Selecting optimum conductors: the illuminated side of some types of solar cells, thin films, have a transparent conducting film to allow light to enter into the active material and to collect the generated charge carriers. Typically, films with high transmittance and high electrical conductance such as indium tin oxide, conducting polymers or conducting nanowire networks are used for the purpose. 2) Promoting light scattering at surfaces: this can be achieved by lining the light-receiving surface of the cell with nano-sized metallic (e.g. silver, aluminum, gold) studs such that light reflects off these studs at an oblique angle to the cell, increasing the length of the light path through the cell and increasing the number of photons absorbed by the cell. 3) Adding rear surface passivation: chemical deposition of a rear-surface dielectric passivation layer stack that is also made of a thin silica or aluminium oxide film topped with a silicon nitride film helps to improve efficiency in silicon solar cells. 4) Improving bifacial panels: enhanced collection of solar energy from back-side “dead spaces” using specific reflecting surfaces.

The sun produces light over a large range of wavelength, often referred to as the solar spectrum. No single-material PV cell is effective over the full range of the solar spectrum. Photovoltaic solar cells rely on the photo-excitation across the semiconducting bandgap, which is an inherent property of the material. Semiconductors have weak adsorption of light possessing photon energy less than their bandgap. This adsorption is related to atom-photon scattering which doesn't create many harvestable electron-hole pairs. Additionally, light-energy in excess of the bandgap, is often lost to thermalization processes. Stacking multiple solar cells tuned to multiple bands in the solar spectrum (e.g. Tandem solar cell) or using multiple materials in the light adsorption region (heterojunction or multijunction solar cells) allow for a wider utilization of the sun's spectrum. Very recently, the world record for solar cell efficiency was demonstrated at 47.1% by using III-V multi-junctions (and concentrator lenses). These solutions also present significant complexity and cost in their manufacture, limiting commercial applications to niche markets, like non-terrestrial power generation. Another solution to utilize more of the solar spectrum is to employ up-conversion or down-shifting materials into the solar cell. Up-conversion materials adsorb multiple photons of low energy and emit light of higher energy; while down shifting materials take light of high energy and luminesce lower energy light. Applied to photovoltaic devices, these materials take light outside the effective spectral range of the solar cell and create harvestable photons. To date, the cost and low conversion yields leave these materials in the realm of academic research.

There remains, in addition to all of these designs and improvements, an opportunity to optimize light capture from varying incident angles, as occasioned by the daily movement of the sun. Scientific research in this area is sparse. Past developments include “3D” structures in photovoltaic devices that are in the nanometer to tens-of micrometer length scale and surfaces designed for light scattering to reduce reflection in the active photovoltaic materials. For example, MIT has tested three different 3D modules for solar panels. Nanostructured materials are considered to offer better antireflection properties, which allow more sunlight to enter a solar cell. These could also be used to restrict the wasteful emission of radiation when electrons and holes recombine. Electrodes made from a grid of nanowires can be almost perfectly transparent. Furthermore, a Dutch research group has found that nanocylinders can supercharge solar cell performance in several ways. Although superficially similar to quantum dot arrays, nanocylinders are made from an insulating material instead of a semiconductor and, rather than absorbing light, they simply have a different refractive index than the surrounding material. As a result, certain wavelengths of light bounce off the array, whereas others are transmitted.

Various directional means, rotatable or tiltable to orient solar panels in an optimum position to gather the most sunlight possible over the day taking into account the path of the sun are also known in the art. Usually, such solar panels are provided in arrays comprising a number of rows and columns, thus covering a substantial amount of land, especially useful agricultural areas. Even if these arrays are provided on the roof surface of buildings, this usually makes these surfaces not otherwise usable. By way of example, WO 2016/074342 discloses a horizontal single-axis solar tracker support stand and a linkage system thereof, comprising a vertical column, a main beam that is rotatable and is provided on the vertical column, and a support frame fixed to the main beam and able to rotate with the main beam. The fixed support frame horizontally extends in a north-south orientation and is provided with a solar cell assembly arranged so as to form an inclined angle relative to a horizontal plane. When used in the northern hemisphere, the solar cell assembly is arranged at an inclined angle such that its northern side is higher than its southern side; the opposite angle of inclination is used in the southern hemisphere. This type of installation aims at providing lines of solar cell assemblies being orientable in an efficient way following the sun. It solves a problem of providing a flat single-axis solar tracking structure which is not as easy to be damaged as an inclined single-axis structure and, at the same time, does not exhibit the problem of lower solar energy collection known from existing flat single-axis solar tracking structures.

Despite the areas described above, there is still a need for photovoltaic power generator structures/solar cells which can exhibit an improved conversion rate from solar radiations over a wide range of light incident angles to generate electric power over the full course of the day. It is an object of the invention to obviate or mitigate these disadvantages. This background information is provided to reveal information believed by the applicant to be of possible relevance to the present invention. No admission is necessarily intended, nor should be construed, that any of the preceding information constitutes prior art against the present invention

### SUMMARY OF THE INVENTION

It is an object of the present invention to provide a photovoltaic lined optical cavity in which light trapping is achieved primarily through integral reflections.

It is an object of the present invention to provide an improved solar cell which capitalizes on the optimal collection of solar energy from varying incident angles.

The present invention provides a solar cell comprising:
i) an optical cavity for optimal light trapping, even incidental/non-line of sight light trapping, said optical cavity comprising a top end having an exposed outer area to receive light and at least two other areas forming, along with the top end, a “cavity shape”;
ii) a photovoltaic layer partially or fully lining the cavity shape, of the optical cavity;
iii) optical core fill, within the optical cavity; and
iv) a base substrate supporting at east the optical cavity and optical core fill.

The present invention further provides a solar cell in which a photovoltaic layer, optical core fill and a cavity shape define a highly customizable light management system.

The present invention further provides a solar cell in which a photovoltaic layer(s) and optical core fill together, form customizable light management components.

The present invention further provides a solar power generation unit comprising more than one solar cell, wherein each solar cell comprises an optical cavity for optimal light trapping, even incidental/non-line of sight light trapping; said optical cavity comprising a top end having an exposed outer area to receive light and at least two other areas forming, along with the top end, a “cavity shape”; a photovoltaic layer partially or fully lining the cavity shape, of the optical cavity; optical core fill, within the optical cavity; and a base substrate supporting the optical cavity and optical core fill. In this way, each solar cell having its' own customizable light management components, may capture different incident light angles, may have differing efficiencies effective over different spectral ranges, may increase or decrease light impedance, and may selectively and purposely transfer light between cells for optimal energy capture.

Furthermore, the base substrate not only provides support for the optical cavity and optical core fill but comprises a material with sufficient integrity and strength to (as desired) provide support against mechanical loads, to house and protect electronic components and to define, in whole or part, the cavity shape.

The present invention also includes a variety of methods of manufacture of the solar cell as described herein.

Overall, what is achieved with the optical cavity design, solar cell and solar power generation unit of the present invention is a multitude of improvements over prior known solar cells. Selection of the optical cavity shape, optical fill and the composition and arrangement of the photovoltaic layer in each solar cell (in a larger array) means that light can optimally be collected, even when the solar power generation unit is in a flat, immovable set-up, for example, in fixed roofs, built into roadways, other tarmacs, sidewalks, parking lots, and bridges. In many of these use cases, the solar power generation unit or array must be load-bearing and the unique structure of both the base substrate and optical core fill enables this. The combination of a solar cell which is highly efficient in light management and in energy collection across varying incident angles, while at the same time being structurally integral and versatile enough for new uses (such as in roadways and parking lots) is not found in the art.

### DRAWINGS

FIG. 1 is cross-sectional plan view of a 3D photovoltaic lined optical cavity showing light being absorbed in the photovoltaic material lining of the optical cavity and the reflected light being directed into the cavity for additional passes;

FIG. 2 is a further cross-sectional plan view diagram of a 3D photovoltaic lined optical cavity;

FIG. 3 is a further cross-sectional plan view of an array comprising 3D photovoltaic lined optical cavities;

FIG. 4 is a further cross-sectional plan view of a photovoltaic lined optical cavity with sample cases where the optical core is engineered to have light management features;

FIG. 5 is a further cross-sectional view of a 3D photovoltaic lined optical cavity with multiple types of PV;

FIG. 6 is a cross-sectional plan view diagram of a 3D photovoltaic lined optical cavity outlining cases where semi-transparent solar cells could be used;

FIG. 7 is a cross-sectional view of a 3D photovoltaic lined optical cavity, having a rough patterned lining;

FIG. 8 is a cross-sectional view of a 3D photovoltaic lined optical cavity in which mirror are employed as partial lining of the cavity;

FIG. 9 is a cross-sectional plan view of 3D photovoltaic lined optical cavity which shows the use of spectral manipulation material as a cavity lining;

FIG. 10 is a schematic of a basic method for fabrication of 3D photovoltaic lined optical cavities using the 3D Assemble Method;

FIG. 11 is a schematic of a basic method for fabrication of 3D photovoltaic lined optical cavities using the 3D Synthesis Method; and

FIG. 12 illustrates some preferred dimensions of the optical core used as a substrate in 3D photovoltaic lined optical cavities.

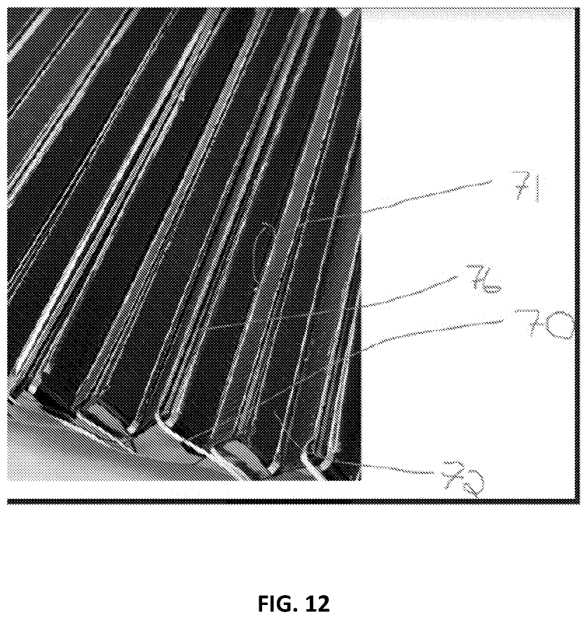

The figures depict embodiments of the present invention for purposes of illustration only. One skilled in the art will readily recognize from the following description that alternative embodiments of the structures and methods illustrated herein may be employed without departing from the principles of the invention described herein.

### DETAILED DESCRIPTION OF THE PREFERRED EMBODIMENTS

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

The invention is susceptible to many variations, including scaling for capacity, in so long as design and process parameters are maintained. Accordingly, the drawings and following description of the preferred embodiments are to be regarded as illustrative in nature, and not as restrictive.

### Terms

The term “device” means any machine, manufacture and/or composition of matter, unless expressly specified otherwise, in accordance with the invention. In some cases here, it may refer to a solar cell, while in other cases it may refer to an array of solar cells or a solar power generation unit comprising more than one solar cell.

The term “invention” and the like mean “the one or more inventions disclosed in this application”, unless expressly specified otherwise.

The terms “an aspect”, “an embodiment”, “embodiment”, “embodiments”, “the embodiment”, “the embodiments”, “one or more embodiments”. “some embodiments”, “certain embodiments”, “one embodiment”, “another embodiment” and the like mean “one or more (but not all) embodiments of the disclosed invention(s)”, unless expressly specified otherwise.

The term “variation” or “variant” of an invention means an embodiment of the invention, unless expressly specified otherwise.

A reference to “another embodiment” or “another aspect” in describing an embodiment does not imply that the referenced embodiment is mutually exclusive with another embodiment (e.g., an embodiment described before the referenced embodiment), unless expressly specified otherwise.

The terms “including”, “comprising” and variations thereof mean “including but not limited to”, unless expressly specified otherwise.

The terms “a”, “an” and “the” mean “one or more”, unless expressly specified otherwise. The term “plurality” means “two or more”, unless expressly specified otherwise.

The term “herein” means “in the present application, including anything which may be incorporated by reference”, unless expressly specified otherwise.

The phrase “at least one of”, when such phrase modifies a plurality of things (such as an enumerated list of things) means any combination of one or more of those things, unless expressly specified otherwise. For example, the phrase “at least one of a widget, a car and a wheel” means either (i) a widget, (ii) a car, (iii) a wheel, (iv) a widget and a car, (v) a widget and a wheel, (vi) a car and a wheel, or (vii) a widget, a car and a wheel. The phrase “at least one of”, when such phrase modifies a plurality of things does not mean “one of each of” the plurality of things.

Numerical terms such as “one”, “two”, etc. when used as cardinal numbers to indicate quantity of something (e.g., one widget, two widgets), mean the quantity indicated by that numerical term, but do not mean at least the quantity indicated by that numerical term. For example, the phrase “one widget” does not mean “at least one widget”, and therefore the phrase “one widget” does not cover, e.g., two widgets.

The phrase “based on” does not mean “based only on”, unless expressly specified otherwise n other words, the phrase “based on” describes both “based only on” and “based at least on”. The phrase “based at least on” is equivalent to the phrase “based at least in part on”.

The term “represents” and like terms are not exclusive, unless expressly specified otherwise. For example, the term “represents” do not mean “represents only”, unless expressly, specified otherwise. In other words, the phrase “the data represents a credit card number” describes both “the data represents only a credit card number” and “the data represents a credit card number and the data also represents something else”.

The term “whereby” is used herein only to precede a clause or other set of words that express only the intended result, objective or consequence of something that is previously and explicitly recited. Thus, when the term “whereby” is used in a claim, the clause or other words that the term “whereby” modifies do not establish specific further limitations of the claim or otherwise restricts the meaning or scope of the claim.

The term “e.g.”, “ex” and like terms mean “for example”, and thus does not limit the term or phrase it explains. For example, in a sentence “the computer sends data (e.g., instructions, a data structure) over the Internet”, the term “e.g.” explains that “instructions” are an example of “data” that the computer may send over the Internet, and also explains that “a data structure” is an example of “data” that the computer may send over the Internet. However, both “instructions” and “a data structure” are merely examples of “data”, and other things besides “instructions” and “a data structure” can be “data”.

The term “respective” and like terms mean “taken individually”. Thus, if two or more things have “respective” characteristics, then each such thing has its own characteristic, and these characteristics can be different from each other but need not be. For example, the phrase “each of two machines has a respective function” means that the first such machine has a function and the second such machine has a function as well. The function of the first machine may or may not be the same as the function of the second machine.

The term “i.e.” and like terms mean “that is”, and thus limits the term or phrase it explains. For example, in the sentence “the computer sends data (i.e., instructions) over the Internet”, the term “i.e.” explains that “instructions” are the “data” that the computer sends over the Internet.

In the description, corresponding reference numbers are used throughout to identify the same or functionally similar elements. Relative terms such as “horizontal,” “vertical,” “up,” “down,” “top” and “bottom” as well as derivatives thereof (e.g., “horizontally,” “downwardly,” “upwardly,” etc.) should be construed to refer to the orientation as then described or as shown in the drawing figure under discussion. These relative terms are for convenience of description and are not intended to require a particular orientation unless specifically stated as such. Terms including “inwardly” versus “outwardly,” “longitudinal” versus “lateral” and the like are to be interpreted relative to one another or relative to an axis of elongation, or an axis or center of rotation, as appropriate. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. The term “operatively connected” is such an attachment, coupling or connection that allows the pertinent structures to operate as intended by virtue of that relationship.

As used herein, the term “geometric prism” refers to a three-dimensional shaped structure, for example a microstructure, having top and bottom faces connected by flat or curved sidewalls. This type of shape is also referred to herein as a microprism, and includes cylinders, cubes, cuboids, rectangular prisms, hexagonal prisms, and the like. In various embodiments, the top and bottom faces are parallel and are similarly sized and shaped. However, it is also envisioned that the structure may have differently sized and/or shaped top and bottom faces, for example in accordance with a frustra-conical shape.

As used herein, the term “conical shape” refers to a three-dimensional shaped structure having a top face and non-parallel sidewalls tapering to a point or tapering to a bottom face having a small but possibly nonzero area. The absence or reduction in size of the bottom face mitigates the need for a photovoltaic structure at this location. The conical shaped structures can have a cross section shape of circle, triangular, square, pentagon, hexagon, etc. Conical shaped structures may be cones, pyramids, or the like.

Unless defined otherwise, all technical and scientific terms used herein have the same meaning as commonly understood by one of ordinary skill in the art to which this invention belongs.

Additionally, the embodiments in the detailed description will be described with sectional and/or plan views as ideal exemplary views of the inventive concept. In the figures, the thicknesses of layers and regions are exaggerated for clarity of illustration. Accordingly, shapes of the exemplary views may be modified according to manufacturing techniques and/or allowable errors. Therefore, the embodiments of the inventive concept are not limited to the specific shape illustrated in the exemplary views but may include other shapes that may be created according to manufacturing processes. Areas exemplified in the drawings have general properties and are used to illustrate a specific shape of a device region. Thus, this should not be construed as limited to the scope of the inventive concept.

Any given numerical range shall include whole and fractions of numbers within the range. For example, the range “1 to 10” shall be interpreted to specifically include whole numbers between 1 and 10 (e.g., 1, 2, 3, 4, . . . 9) and non-whole numbers (e.g. 1.1, 1.2, . . . 1.9).

Where two or more terms or phrases are synonymous (e.g., because of an explicit statement that the terms or phrases are synonymous), instances of one such term/phrase does not mean instances of another such term/phrase must have a different meaning. For example, where a statement renders the meaning of “including” to be synonymous with “including but not limited to”, the mere usage of the phrase “including but not limited to” does not mean that the term “including” means something other than “including but not limited to”.

Neither the Title (set forth at the beginning of the first page of the present application) nor the Abstract (set forth at the end of the present application) is to be taken as limiting in any way as the scope of the disclosed invention(s). An Abstract has been included in this application merely because an Abstract of not more than 150 words is required under 37 C.F.R. .sctn. 1.72(b). The title of the present application and headings of sections provided in the present application are for convenience only and are not to be taken as limiting the disclosure in any way.

Numerous embodiments are described in the present application and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural and logical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

No embodiment of method steps or product elements described in the present application constitutes the invention claimed herein, or is essential to the invention claimed herein, or is coextensive with the invention claimed herein, except where it is either expressly stated to be so in this specification or expressly recited in a claim.

### II. Overview

In one aspect, the present invention provides a solar cell comprising:
i) an optical cavity for optimal light trapping, even incidental/non-line of sight light trapping, said optical cavity comprising a top end having an exposed outer area to receive light and at least two other areas forming, along with the top end, a “cavity shape”;
ii) a photovoltaic layer partially or fully lining the cavity shape, of the optical cavity;
iii) optical core fill, within the optical cavity; and
iv) a base substrate supporting at least the optical cavity and optical core fill.

One key aspect of the invention is that the photovoltaic layer, the optical core fill and the cavity shape define a highly customizable “light management system” which extends in operability when more than one cell comprising these features is then arranged in an array of multiple solar cells, and each cell can then offer a specific and optionally different photovoltaic layer, the optical core fill and the cavity shape variation from its adjacent neighbouring solar cells. Such arrays and; in particular, how side-by-side, row by row, set by set cells are created, optimizes light capture in a given environment.

Another key aspect of the present invention is the functionality offered by the base substrate. In considering all aspects of the invention, the figures herein and the methods of manufacture disclosure, the important of this component will become even more apparent.

In a preferred form, the photovoltaic layer comprises a material selected from the group consisting of any solar cell (including those which are bi-facial and semi-transparent) mirrors and any spectral manipulation element.

In a preferred form, the optical core comprises any transparent material that exhibits one or more light management functions including lensing, anti-reflection, and spectral manipulations over a wide variation of solar incident angles.

In a preferred form, the photovoltaic layer and the optical core fill together form light management components selected from the group consisting of reflecting components (including but not limited to mirrors, antireflection coating, thin-films); refraction components (including but not limited to prisms, gratings, and engineered thin-films; transmission components (including but not limited to bi-direction interfaces, transparent materials); concentration components (including but not limited to lens, concave mirrors, optical concentrators); scattering components (including but not limited to diffusors, micro/nano-patterned surfaces); and spectral manipulation components (including but not limited to up-conversion or down-conversion materials, and quantum dots).

In a preferred form, the substrate comprises a material with sufficient integrity and strength to provide support against mechanical loads. Preferably, the substrate houses and protects electronic components. In some embodiments, the substrate defines, in whole or part, the cavity shape. In some embodiments, the substrate comprises or itself defines a mechanical damping means, against shocks and vibrations. By way of example, a mechanical damping means may comprise one of liquid gaps or air gaps in the substrate.

In a preferred form, the optical cavity comprises any shape which internally reflects and/or directs light optimally to photovoltaic layer, regardless of incident angle of light. Such shapes include but are not limited to cylinder, geometric prism, circle, cone, pyramid, cube, cuboid, hexagon, and rectangle.

A further key aspect of the invention is a solar power generation unit comprising more than one solar cell, wherein each solar cell comprises an optical cavity for optimal light trapping, even incidental/non-line of sight light trapping, said optical cavity comprising a top end having an exposed outer area to receive light and at least two other areas forming, along with the top end, a “cavity shape”; a photovoltaic layer partially or fully lining the cavity shape, of the optical cavity; optical core fill, within the optical cavity; and a base substrate supporting the optical cavity and optical core fill.

For each solar cell, the photovoltaic layer, the optical core fill and the cavity shape define a customizable light management system and each solar cell within the solar power generation unit may be customized to be efficient within given bands of the solar spectrum. In one aspect, unused or unusable light from one solar cell is directable to another solar cell, for more efficient conversion. In one aspect, the light management system is also a structural, vibrational and shock-absorbing support.

Methods of Use:

Although the solar cell and solar power generation unit of the invention are widely functional across various platforms, it is to be noted that they find particularly advantageous use as application specific modules under walkways, driveways, patios, roadways and on roofs. The units can be mounted directly on flat concrete, recycled plastic pavers or within an interface layer that provides levelling and cabling functionality. Hybrid systems combine photo-voltaic output with solar thermal and optionally de-icing options.

### III. Further Details and Description of Figures

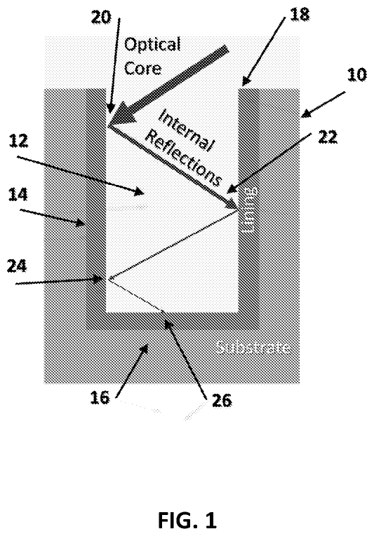

As shown in FIG. 1, the solar cell generally shown at 10 comprises an optical cavity 12, active light management lining (primary PV) 14, optical core 18 and supporting substrate 16. The three elements (14, 16 and 18) work in conjunction with each other to manage the light within the photovoltaic lined optical cavity as well as the various other functions needed for a working solar power generation unit, such as, for example, mechanical support, environmental protection of sensitive elements, housing of the wiring and electronics, heat management, etc. Together their parts will form a solar power generation unit that in addition to an effective light trapping structure over the various incident angles of the sun, also serves as functional structural support, critical to a practical application. The supporting substrate may define the shape of the “photovoltaic lined” optical cavities. The base substrate, as noted above, can be made of a magnitude of materials, and could include sections with air gaps, or liquids in addition to load bearing solid materials. Gaps of liquid or air may be used for mechanical damping of mechanical shocks and vibrations. FIG. 1 shows a cross-sectional plan view of a 3D photovoltaic lined optical cavity showing light being absorbed in the photovoltaic material lining of the optical cavity and the reflected light being directed into the cavity for additional passes.

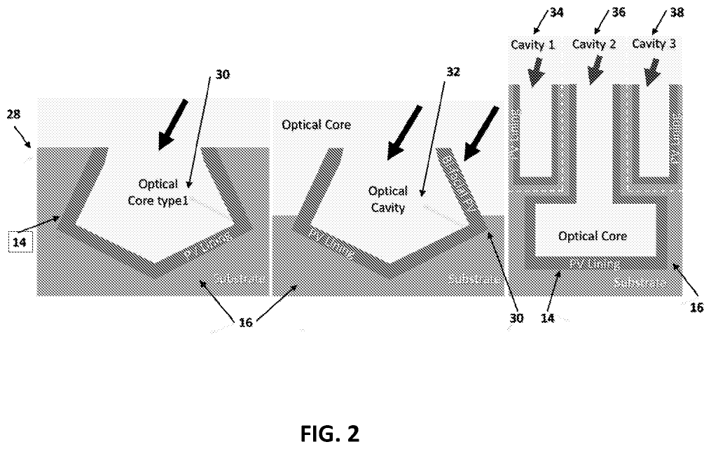

FIG. 2 shows a cross-sectional diagram of a conceptual 3D photovoltaic lined optical cavity which are examples of non-line of sight 3D photovoltaic lined optical cavities generally shown as 28 Substrate 16 supports each cavity/core 32/34/36/38. Left: Simple 3D structure, best for combination with optical concentration elements such as those outlined in FIG. 2. Middle: 3D photovoltaic-lined optical cavity in which bi-facial cells 30 are applied. Right: Set of PV-lined optical cavities in which the outer ones are 3D line-of-sight cavities and the middle is a 3D non-line-of-sight cavity.

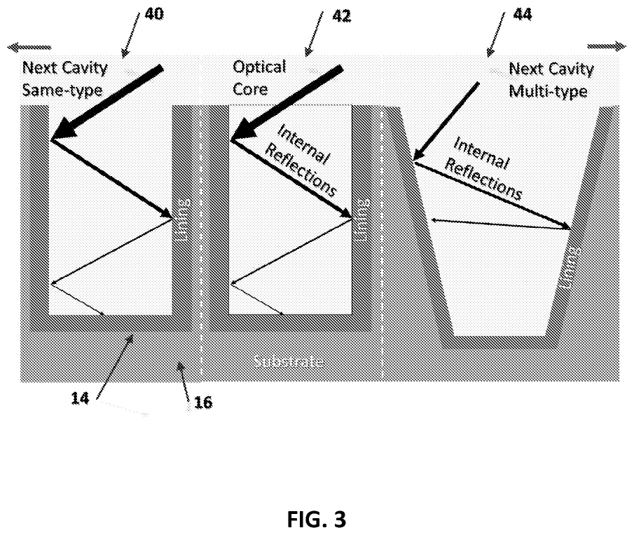

FIG. 3 is a further cross-sectional plan view of an array comprising 3D photovoltaic lined optical cavities. This example shows the combination of optical cavities of the same time or optical cavities of multiple types.

Generally, the light trapping structures of the present invention comprise a light management component arranged with one or more of any configuration photovoltaic, reflective, or spectral conversion materials forming an “optical cavity”. A light management component may be any component or interface that is used to direct light within the photovoltaic cells. By way of example, these include, but are not limited to:
Photovoltaic lining: by way example: a solar cell of any type, including bi-facial or semi-transparent cells
Reflection components: by way of example: mirrors, antireflection coating, highly reflective materials, thin-films
Refraction components: by way of example, prisms, gratings, engineered thin-films
Transmission components: by way of example: bi-direction interfaces, transparent materials
Concentration components: by way of example: lens, concave mirrors, optical concentrators
Scattering components: by way of example: diffusors, micro/nano-patterned surfaces
Spectral Manipulation Components: by way of example: up-conversion or down-conversion materials, quantum dots

Highly reflective materials (films or coatings) can be formed using any suitable reflective material including, but not limited to, reflective polymers such as polyethylene terephthalate (PET), triacetate cellulose (TAC), and ethylene tetrafluoroethylene (ETFE), reflective metals such as aluminum, silver, gold, copper, palladium, platinum, or alloys, ceramic materials, paint, or materials formed in the prism shaped, or combinations thereof.

The core light management component includes the solar cells which will line some or all of sidewalls of the photovoltaic lined optical cavity as these components generate electrical power. Of note, given the highly engineered nature of solar cells, other light management feature may naturally be incorporated into the photovoltaic lining. The present invention is agnostic to the materials used, as long as desired light management functionality is achieved. Any known (or as yet undiscovered) semiconductor may be used to generate a photovoltaic effect and may be used within the scope of the invention.

The shape of the core invention may be any structure that forms an optical cavity in which internal reflections direct light into power producing photovoltaic elements. Note that during the day the solar incident angle of light will vary. This is especially true in case where scattering of objects produces an ambient background of light at almost all angles. The invention includes any shape with feature size such the geometric optics (i.e. ray trace) could be used (doi: 10.1103/PhysRevLett.97.120404). Given that the solar spectrum extends out to out to 2-3 um (useable power) the feature size of the structure should be great than 20-30 um.

The core element, the 3D photovoltaic lined optical cavity may be combined with other core elements to yield a power generation unit that is arbitrarily large. Optical cavities could be placed together, as FIG. 3 exemplifies, the power generation unit could be expanded by simply adding more cavities. The array could be assembled by combining existing cavities or by building on a larger substrate. Note, the optical cavities may be ordered or randomly orientated, or they may be homogenous or of multiple types (ordered or randomly configured).

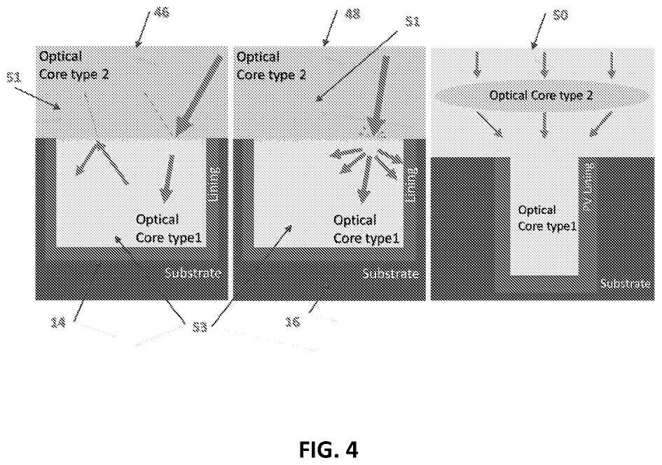

FIG. 4 is a further cross-sectional plan view of a photovoltaic lined optical cavity with sample cases where the optical core is engineered to have light management features. Left: case of where the index of refraction matched to provide transmission in one direction but reflection in the other, thus capturing light in the photovoltaic lined cavity. A thin optical anti-reflection thin film could achieve the same effect. Middle: case where a patterned or rough surface in employed in the optical core to scatter light randomly into the optical core. Right: a case where the part of the optical core is fashioned into a concentrating lens. Optical core type 2 is shown as 51, optical core type 1 is shown as 53 for three cells, 46, 48 and 50.

The optical core of the photovoltaic lined cavity is a critical part of the light management system of the invention. The optical core will serve dual roles as encapsulation, structural support, and potentially vibrational damping. The optical index of refraction of the optical core must be engineered to supplement the light-management features of light capturing optical cavities. This is an engineering feature as the solar angle of incident varies daily/seasonally and the solar spectrum runs over a broad range. Total energy output is the core design feature. The optical core can be designed with a degree of complexity as FIG. 4 shows some examples of. Ideally the material is chosen such that the optical transmission is high, such to reduce optical losses. Now the core of the photovoltaic lined cavity can be engineered quite clever. Multi-materials can be used in the core to yield an anti-reflection effect. Either through the addition of multiple thin transparent layers, to yield thin film interference, or through tuning the index of refraction to decrease optical reflection out. Similarly, reflection of multiple wavelengths of sunlight can be used to separate light and direct into various sections of the cavity, which could be lined with light specific photovoltaic materials. Now the optical core could be shaped into a lens, which requires design work in conjunction with light trapping structures of the photovoltaic lined optical cavity. There are two use cases of this function. One is a passive lens, designed to stay static and work over a large range of solar incident angles. Another is a concentration lens designed to work at one solar incident angle, where some faction of tracing is needed for this particular use case. As the optical core could form almost an optical element, the case of an optical diffuser should also be mentioned. Optical diffuse scattering is particularly useful for capturing light at low incident angles, such as the case during mornings and evenings or the natural ambient sunlight scattering/reflection of landscape objects.

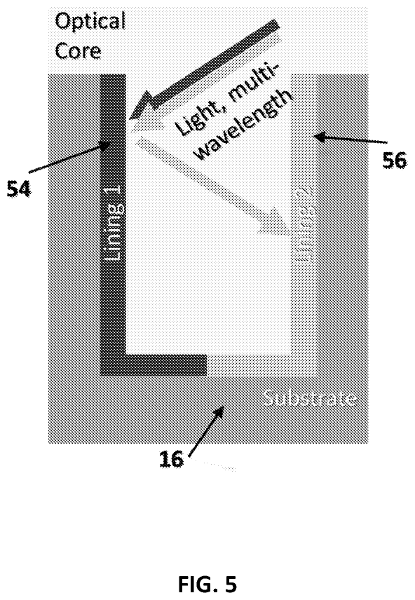

A key feature of the 3D photovoltaic lined optical cavities of the invention is that multiple types of solar cells may be used as the cavity lining. This allows the 3D photovoltaic lined optical cavities to provide a unique solution to a fundamental challenge in solar power generation; the solar spectrum is quite broad compared to the efficient energy capture range of any existing single material solar cell. By choosing solar cells with multiple spectral absorption bands and constructing the 3D photovoltaic lined optical cavity such that unused or unusable light from one solar cell is directed to another solar cell where said light is efficiently converted, the power generation unit effectively covers a large spectral range The right side of FIG. 5 illustrates an example of this process. A similar effect could be achieved with single multi-material tandem solar cells. The 3D photovoltaic lined cavity provides some advantages over traditional solar cells, mainly the solar cells could be manufactured independently. This design lifts challenges such as material matching or current matching the solar cells.

FIG. 5 is a further cross-sectional plan view of a 3D photovoltaic lined optical cavity. In this case multiple types of photovoltaic (54 and 56) are used. This is an example where solar cells with different spectral efficiencies are used to line the optical cavity, one engineered for absorption of orange (54) and the other for the absorption of green (56). In this example, the orange is absorbed on the first pass, but the green is first reflected then adsorbed on the second pass, as shown by the arrows.

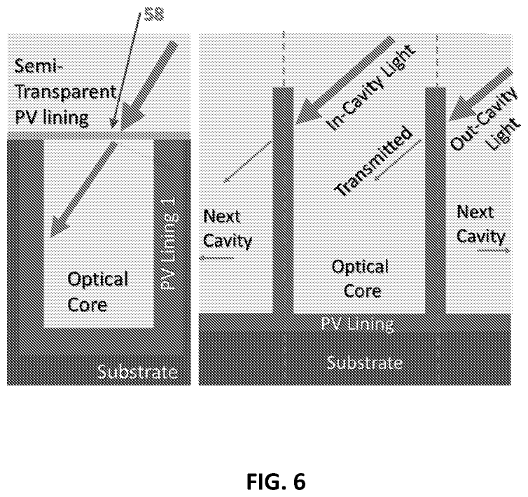

As any solar cell could be used for the 3D photovoltaic lined optical cavity, semi-transparent solar cells could be considered. Semi-transparent solar cells will allow for the partial transmission of light, either a generally attenuation or partial transmission of the broad solar spectrum. Such is shown in FIG. 6. The semi-transparent photovoltaic lining acts as an anti-flection feature much like optical core elements shown in FIG. 4. Recall that the photovoltaic material is highly engineered with the option of many light management features being built into the engineered structure of the material. Another option is the utilization of photovoltaic lining in multiple optical cavities such as the case where light could be transmitted across an array of cavities or a bi-facial solar cell lining dual cavities as shown in the right side of FIG. 6.

FIG. 6 is a cross-sectional plan view diagram of a 3D photovoltaic lined optical cavity outlining cases where semi-transparent solar cells could be used. Left: In this case a semi-transparent solar cell is used to line the top of the optical cavity, allowing partial light to transmit. Right: An example where semi-transparent solar cells allow transmission into the next 3D photovoltaic lined optical cavity, a good example of the use of bi-facial solar cells.

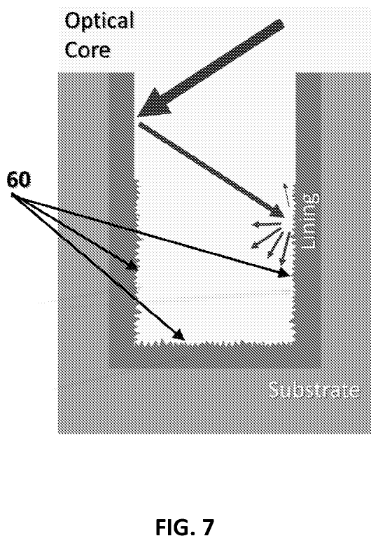

FIG. 7 is a cross-sectional view of a 3D photovoltaic lined optical cavity. In this case the lining has patterned or rough surfaces (60) to induce scattering of light within the optical cavity. The internal reflections within the 3D photovoltaic lined optical cavity do not have to be specular. Diffuse scattering in non-specular directions will still be captured by the macroscopic scale optical cavity and may be used as features to yield an efficient light trapping structure. Optional surfaces will vary between smooth and shiny to rough and diffuse, as illustrated in FIG. 7. Even nano or micro-scale structures, often employed in solar cells (refs) could be utilized in the 3D photovoltaic lined optical cavity, assuming the overall power output was optimized. Similarly, anti-reflection coating, fabricated by deposition of a thin-optical window or dielectric layer directly on the photovoltaic lining. If nothing else theses layers act as element protection for the often air-sensitive photovoltaic materials.

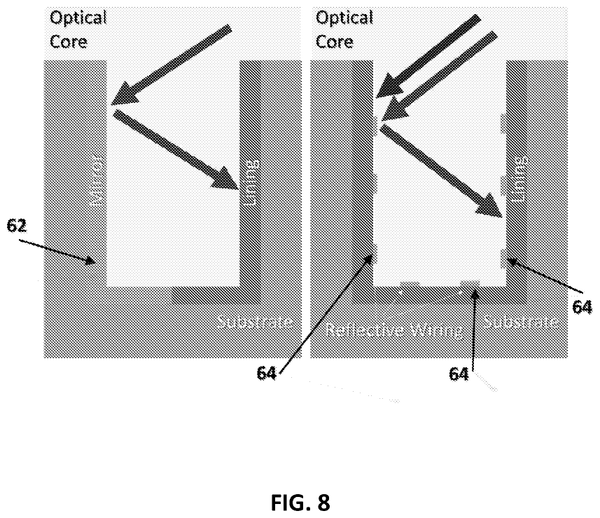

Non photovoltaic material could also be employed in the 3D photovoltaic lined cavity in a light management capacity. As shown in the examples of FIG. 8 which is a cross-sectional view of a 3D photovoltaic lined optical cavity in which mirror (62) are employed as partial lining of the cavity. Left: In this case a mirror is directly employed for the purpose of redirecting light to power generating photovoltaic material. Right: In this case the electrical contacts (64) are dual purposed as internal mirrors within the cavity. These light management elements may serve dual purposes within the complete power generating unit, taking on structural, conducting (for example, wires), chemical protection, or thermal management abilities. These elements may also be added to reduce the total cost of the unit, for example a mirrored surface is typical less expensive then a photovoltaic lined surface. Now of the non-photovoltaic materials that are utilized in the primarily photovoltaic lined optical cavity are mirrored surfaces. Traditional mirrors may be used, such as shiny metallic surfaces, or mirror-like photovoltaic layers. Given the highly engineered nature of solar cells these surfaces could also be used as mirrors, through the natural reflection of the material or a thin-film interference effect. Typically, a specific wavelength range mirror (known in the art) would be employed with photovoltaics and a broadband, over the full solar spectrum range. Shiny plastics, dielectric coatings, or other materials could also be employed, either added as structural elements or engineered thin films. Of note, electrical contacts of the solar cells are natural mirrors. Light reflected from the top contacts is still collected as the light is reflect into the photovoltaic lined optical cavity and light reflected from the back contact yields the same effect.

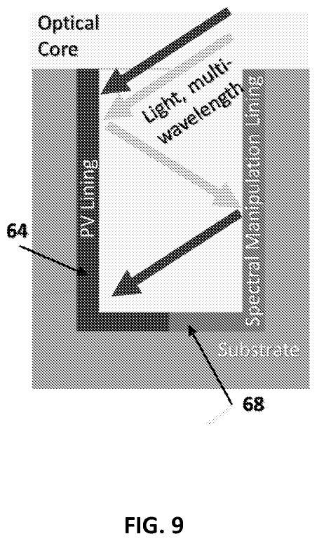

Up or down spectral conversion materials convert high energy photons or low energy photons with energies more suited for semiconductor absorption, as shown in the embodiment of FIG. 9. FIG. 9 is a cross-sectional plan view of 3D photovoltaic lined optical cavity which shows the use of spectral manipulation material as a cavity lining. In this example the photovoltaic (66) would be tuned to orange and the spectral manipulation material (68) coverts green to orange and reflects in into the power producing photovoltaic material. Right: A sample of the useful solar spectrum absorbable by crystalline silicon based solar cells and the spectrum that could be down or up converted to the useful silicon absorption band by know spectral manipulation materials.

These materials are particularly suited for photovoltaic lined optical cavity, beyond the typically described application as a thin film on the 2D solar cell. First, the optical core of the element could be made in of these materials, fully or in part. The optical cavity could be lined with these spectrum manipulating materials, much like a different photovoltaic material. Similarly, the photovoltaic lined optical cavity would further direct light into the spectrum specific absorbers much like with a 100% single type photovoltaic cavity or a multi-photovoltaic cavity as shown in FIG. 5.

### IV. Methods of Manufacture

Optical Cavity Methods of Manufacture

The present invention provides two methods of manufacture of the solar cells and solar power generating units of the invention. The first is a method in which solar cells (and other light management components) are pre-manufactured then processed/assembled to fit a structure that forms an optical cavity, referred to as the “3D Assemble Method”. The second is a method in which solar cells are manufactured/synthesized on an existing structure that forms the optical cavity, referred to herein as the “3D Synthesis Method”.

Manufacture follows these basic steps which include:
Manufacture of (partial) starting structure (optical core or substrate)
Assembly/Synthesis of photovoltaic and other light management elements
Encapsulation with additional structure (optical body, environmental sealing)
Assemble into a power generation unit

Manufacture of the Starting Structure

Common to all methods is a base structure that the photovoltaic lined optical cavity would be manufactured on. This structure could later form a complete or partial part of either the optical core or the base substrate. For partial structures, the final assembly would be done later. The structures could be formed from a wide variety of well-known industrial or published methods and materials. Patterned glass, metals, polymers, ceramics, stone, plastics or even patterned spectrum management materials may be used. The core feature of the starting structures is that it contains a cavity or component of a cavity that will later form the core element of the invention.

A wide variety of manufacture methods could be used to the construction of the initial structure given the range of materials. These methods include stamping, bending, indenting, moulding, machining, 3D printing, etching, drop casting, and pouring etc. Any method that yields a patterned material will work and is within the scope of the invention. Of note; a layer for passivation could be applied to ensure the various materials in the invention do not interact, i.e. internally chemically or environmentally sealing the material.

Additive manufacture methods such as 3D printing may be applied with the photovoltaic elements and wire connections treated as a component in a multi-element print. Now, besides placing and sealing the photovoltaic elements, 3D printing can print plastics, stone, cement, polymers, epoxies, metal, conductive 2D materials; even glass and ceramics. Even the electronics that are fundamental for a solar power generation (MPPT, Charge controller, AC-DC conversion, micro-battery or other energy storage) could be added to the system as discreet components to make a true integrated solution.

The main requirement of the optical core is transparent materials and the main requirement for the substrate is the support and housing of wire conduits. The manufacture of the starting structure will set the state for the completion of the photovoltaic lined optical cavity. Key light management features (anti-reflection, lens, mirrors, spectral management materials), heat management features (cooling, heat exchange pipes), electrical system management (wires, electronics, bypass-diodes, sensors, LEDs, solder . . . ) and structural management (supports, vibration damping, environmental seals) could be added to the initial structure.

Assemble Method

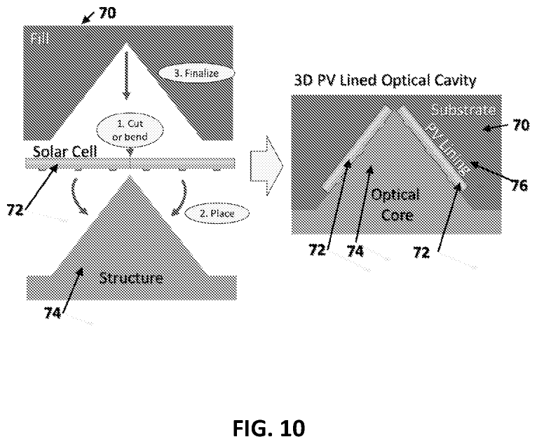

Photovoltaic-lined optical cavities can be fabricated from almost any solar cell with some specific cutting and placing of the pieces. Pre-manufactured solar cells of any shape or size can be cut into almost any size or shape. This will work for any solar cell material set or design concept (crystalline, amorphous, thin-film, mono-Si, poly-Si, multijunction perovskite, CIGS, CdTe, CuS-historical), as long as the cell can support its own weight. Ideally the solar cells will have been designed and optimized for application in a photovoltaic lined optical cavity. It has been found that commercially available solar cells are sufficient for this application. FIG. 10 outlines the basic method for fabrication of 3D photovoltaic lined optical cavities using the 3D Assemble Method.

Cutting methods will vary depending on the material and design used. Generally, most solar cells can be cut with a diamond tip cutting blade, precision water jet, high powered laser, maser, or disrupter. Care must be taken not to damage the solar cell during cutting, as the formation of micro/nano dislocations in crystalline substrates and shorts between the layers of the solar cells are well known. Similar methods could be applied to other light management components (mirrors, spectral management materials, lens) which would later form the photovoltaic lined optical cavity.

The photovoltaic pieces and other light management materials are assembled into an optical cavity by moving them to the correct place with an automatic system (preferred over human assemblage).

Vacuum suction, mechanical manipulation, done by specifically designed machines is the preferred choice. Such automatic assembly is observed in many other non-solar industries, e.g. the automotive assemble line or even in certain cases of module assembly. Sealing the piece to the structure may be by adhesives such as glue epoxy, heat treatment or vacuum sealing methods. Glue, sealing, epoxy, chemical bonding lamination etc. are preferred to attach the assembled light management components to the structure, any reasonable sealing, binding, or lamination method will work.

For the case of flexible solar cells, a sheet or thin film of photovoltaic material may be molded to an existing starting surface to yield photovoltaic lined optical cavities. Common industrial, shaping, indenting, molding, and bending methods could be reasonably applied. It is expected that key cuts in the photovoltaic sheet, either to separate regions or to increase the bendability of a section by removing specific elements within the photovoltaic structure or generally weaken it, are needed to assist the molding of the photovoltaic material to the correct optical cavity shape.

Wiring of the solar cells required specific expertise. Automatic soldering systems that connect solar cells to tabbing wiring is commonly available is the silicon solar cell industry and can be reasonably adapted to the 3D assemble method. A system analogous to an automatic weaving could be employed to direct the wiring to the correct position. Typically, thicker gauge wires are used for bus bars for the high current/voltage conduits. Alternatively, the electrical contact could (partially or fully) be achieved by placing the photovoltaic components on pre-manufactured electrical contact boards that would be part of the substrate. One simple option is to place the solar cells on a uniform conducting surface, ideally for cells with back and front contacts, connecting the back contact in parallel with other photovoltaic components. A more complex option would be connected to a ready-to-solder made PCB board, a natural fit for all-back contact solar cell designs.

The internal wiring and electronics of 3D photovoltaic lined optical cavity may be assembled for optimized energy output of the unit. The photovoltaic elements can be wired in almost any configurations. Fabrication and wiring of the solar cells and set of solar cells to be independent will be easy with the 3D Assemble Method. The individual components are divided before assembling, this is ideal for independent electrical connections that could be combined with MPPT or micro-bypass-diodes.

Synthesis Method

Solar cells may be fabricated from scratch on almost any surface with of a suite of deposition, processing, and synthesis methods of metals, TCOs, optical windows, and semiconducting layers of all levels of doping. The core of this methodology is applying these processes to pre-manufactured structures that will form the basis of an optical cavity as discussed previously.

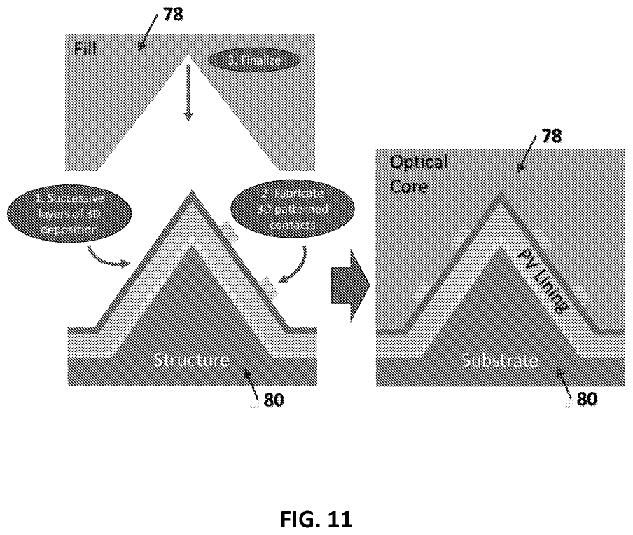

The fabrication of a solar cell involves the combination of multiple layers of semiconductors, doped-semiconductors, electrical contacts, passivation/window layers. The minimum viable solar cell comprises two electrical contacts on a semiconductor that has a built-in differential in the internal electric potential. This is made possible by homo-junctions, heterojunctions, Schottky junctions, electronical gated, or any combination thereof. In fact, there are many 3D capable synthesis methods that could be utilized to make the solar cell and solar array of the invention. For example, gas-phase deposition techniques such as PECVD, ALD, CVD (Plasma-Enhanced Chemical Vapor Deposition, Atomic Layer Deposition, Chemical Vapor Deposition) may be used, or liquid phase methods like solution processed synthesis, electrochemical, spray coating, and bath chemical deposition. These methods are typically done over large areas, requiring additional patterning and separation later. Localized methods, like the 3D printing of solar cells would be required for the addition of patterning often needed for the completion of a solar cell. Though with the utilization of uniform layers, such as transparent conductive oxides, the need for patterning could be avoided. FIG. 11 outlines the general concept of this 3D Synthesis Method.

Contacting of the solar cell in the photovoltaic comes in two varieties, uniform layers of conducting material or the patterning of electrical contacts. For uniform layers the deposition/synthesis methods would still be applicable as described previous. In the case of patterned contacts many known 2D methods could still be employed with line-of-sight structure, such physical vapor deposition through a shadow mask or 3D printing of local metal contacts.

For synthesis of a solar cell on a clean and ready patterned structure the first step is metallization of the bottom contact(s). A clean substrate could be obtained with the deposition of the interface layer (eg oxide) or the cleaning of any substrates. There are a variety of methods (chemical, plasma, thermal/vacuum . . . ) that could clean a 3D substrate. A potential tricky task depending on how 3D the optical cavity is. Techniques can be simple such starting with a conductive structure, ie the structure and the bottom contact are one and the same. Structures in which a reasonable line of sight is presented could utilize a physical vapor deposition method such as thermal or e-beam evaporation, or sputtering. Complex structures would utilize more 3D methods, such a CVD or ALD based processes. For non-line-of sight structures fabrication of the 3D photovoltaic lined solar cells is still possible. There are also a large suite of liquid processed methods, chemical deposition, or electrochemical processes that could be employed. Even 3d printing methods could be employed in non-line-of-sight structures, utilizing the application of liquid drop processed solar cells. One could consider building the structure and solar cell simultaneously in a multi-material 3D print. Another consideration for non-line-of-sight systems is the deposition on partial structures which are line-of-sight then assemble later.

Finalizing the Photovoltaic Lined Optical Cavity

Once the photovoltaic elements are lining the optical cavity (partial or full) the structure needs to complete to make the core element of the invention. Either the optical core or the supporting substrate needs to be added. Note, the fabrication of a photovoltaic lined cavity element can occur in one process or by making pieces and connecting them later. As outlined above any manufacture method could be used (such as encapsulating, pouring, drop casting, attachment . . . ) to finalize the optical core or substrate.

In addition to cuts for shaping and complete separation purposes, the photovoltaic components could be modified for other purposes. The silicon solar industry routinely uses cutting tools to improve the system efficiency of the power generation solar module. For example, in crystalline pn-junction silicon based p-i-n solar cells removal of partial layers in the solar cell are a key part of separating and wiring the sheet into a parallel connected configuration, yielding a high unit output voltage (ref). Additionally, it is common practice to make ½ cut solar cells for use in a solar module (ref). These methods increase the systems output voltage, over output current which is ideal for the support electronics (MPPT, diodes) and reduces the material needed in the wires. These concepts could be reasonably employed in the manufacture of a photovoltaic lined optical cavity.

To yield a power generating unit the core element of the invention, the 3D photovoltaic lined optical cavity may be in an arbitrarily large array, with multiple types of optical cavities. The array may be fabricated as a batch or assembled postproduction with the manufacturing methods outlined previously. Global processes may be reasonably applied to the unit, for example heat treatment or global chemical processing. Also, the power generation unit may be made to be connected to additional encapsulation, support and electronics depending on the application.

### Experimental

To validate the fabrication of 3D photovoltaic lined optical cavities by a deposition method, amorphous silicon pin solar device were explored on 3D glass structures. 3D BK7 optical glass 3D shapes with cm-scale dimensions. In this case the optical core of the photovoltaic lined optical cavity was used as a deposition substrate. Initially, 150 nm of patterned silver grid was deposited on to the glass 3D structure, by thermal evaporation through a shadow mask. The grid consisted of 150 um bus bar that ran the length of the 3D glass structure which as 15 mm long. with 150 um fingers the ran laterally to the top plane with 1.5 mm spacing. A contact pad was located at the h1/h2 boundary and the grid was repeated twice on opposite sides of the 3D optical core. The entire optical core was covered in 150 nm of conducting, optically transparent ZnO:Al by magnetron sputtering. A p-i-n solar cell was deposited on lower half of 3D optical core, followed by the deposition of 300 nm of uniform silver. The device as confirm to be photovoltaic with a solar simulator. It is reasonable that this 3D deposition could be transferred to other designs, material, and methods, given reason time to work out the engineering.

These and other changes can be made to the present device, systems, and methods in light of the above description. In general, in the following claims, the terms used should not be construed to limit the invention to the specific embodiments disclosed in the specification and the claims, but should be construed to include all possible embodiments along with the full scope of equivalents to which such claims are entitled. Accordingly, the invention is not limited by the disclosure, but instead its scope is to be determined entirely by the following claims.

We claim:

1. A solar cell comprising:
i) an optical cavity for optimal light trapping, even incidental/non-line of sight light trapping, said optical cavity comprising a top end having an exposed outer area to receive light and at least two other areas forming, along with the top end, a “cavity shape”;
ii) a photovoltaic layer partially or fully lining the cavity shape, of the optical cavity;
iii) optical core fill, within the optical cavity; and
iv) a base substrate supporting at least the optical cavity and optical core fill.

2. The solar cell of claim 1 wherein the photovoltaic layer comprises a material selected from the group consisting of any solar cell (including those which are bi-facial and semi-transparent) mirrors and any spectral manipulation element.

3. The solar cell of claim 1 wherein the optical core comprises any transparent material that exhibits one or more light management functions including lensing, anti-reflection, and spectral manipulations over a wide variation of solar incident angles.

4. The solar cell of claim 1 wherein the substrate comprises a material with sufficient integrity and strength to provide support against mechanical loads.

5. The solar cell of claim 1 wherein the substrate houses and protects electronic components.

6. The solar cell of claim 1 wherein the substrate defines, in whole or part, the cavity shape.

7. The solar cell of claim 1 wherein the substrate comprises mechanical damping means, against shocks and vibrations.

8. The solar cell of claim 7 wherein the mechanical damping means comprises one of liquid gaps or air gaps in the substrate.

9. The solar cell of claim 1 wherein the optical cavity comprises any shape which internally reflects and/or directs light optimally to photovoltaic layer, regardless of incident angle of light.

10. The solar cell of claim 1 wherein the cavity shape is selected from the group consisting of cylinder, geometric prism, circle, cone, pyramid, cube, cuboid, hexagon, and rectangle.

11. The solar cell of claim 1 wherein the photovoltaic layer, the optical core fill and the cavity shape define a customizable light management system.

12. The solar cell of claim 1 wherein the photovoltaic layer and the optical core fill together form light management components selected from the group consisting of reflecting components (including but not limited to mirrors, antireflection coating, thin-films); refraction components (including but not limited to prisms, gratings, and engineered thin-films; transmission components (including but not limited to bi-direction interfaces, transparent materials); concentration components (including but not limited to lens, concave mirrors, optical concentrators); scattering components (including but not limited to diffusors, micro/nano-patterned surfaces); and spectral manipulation components (including but not limited to up-conversion or down-conversion materials, and quantum dots).

13. A solar power generation unit comprising more than one solar cell, wherein each solar cell comprises an optical cavity for optimal light trapping, even incidental/non-line of sight light trapping, said optical cavity comprising a top end having an exposed outer area to receive light and at least two other areas forming, along with the top end, a “cavity shape”; a photovoltaic layer partially or fully lining the cavity shape, of the optical cavity; optical core fill, within the optical cavity; and a base substrate supporting the optical cavity and optical core fill.

14. The solar power generation unit of claim 13 wherein for each solar cell, the photovoltaic layer, the optical core fill and the cavity shape define a customizable light management system and each solar cell within the solar power generation unit may be customized to be efficient within given bands of the solar spectrum.

15. The solar power generation unit of claim 14 wherein unused or unusable light from one solar cell is directable to another solar cell, for more efficient conversion.

16. The solar power generation unit of claim 14 wherein the light management system is also a structural, vibrational and shock-absorbing support.
